(19) United States
(12) Patent Application Publication
(10) Pub. No.: US 2026/0215105 A1
(43) Pub. Date: Jul. 23, 2026

(54) DISPLAY DEVICE AND ELECTRONIC APPARATUS INCLUDING THE SAME

(71) Applicant: SAMSUNG DISPLAY CO., LTD., YONGIN-SI (KR)

(72) Inventors: Hyomin KIM, Yongin-si (KR); SUN PARK, Yongin-si (KR); SUK HOON KU, Yongin-si (KR)

(21) Appl. No.: 19/399,881

(22) Filed: Nov. 25, 2025

(30) Foreign Application Priority Data
Jan. 17, 2025 (KR) 10-2025-0007454
May 13, 2025 (KR) 10-2025-0062177

(51) Int. Cl. H10K 59/124

(52) U.S. Cl. CPC H10K 59/124

(57) ABSTRACT

A display device includes a base layer, a first insulation layer, an insulation pattern, a second insulation layer, a capacitor, a transistor, and a light-emitting element. The capacitor includes a first electrode which is disposed between the first insulation layer and the second insulation layer and covers the insulation pattern, and a second electrode which is disposed on the second insulation layer.

### CROSS-REFERENCE TO RELATED APPLICATIONS

This U.S. non-provisional patent application claims priority under 35 U.S.C. § 119 of Korean Patent Application Nos. 10-2025-0007454, filed on Jan. 17, 2025, and 10-2025-0062177, filed on May 13, 2025, the disclosure of which is incorporated by reference herein.

### 1. TECHNICAL FIELD

The present disclosure is directed to a display device and an electronic apparatus including the same, and more particularly, to an ultra-high resolution display device and an electronic apparatus including the same.

### 2. DISCUSSION OF RELATED ART

Multimedia electronic apparatuses such as televisions, mobile phones, tablet computers, navigation systems, and game consoles include a display device for present images. Recently, various electronic apparatuses are being developed for implementing augmented reality (AR), virtual reality (VR), mixed reality (MR), and extended reality (XR). These electronic apparatuses demand a high-resolution display device to deliver enhanced visual performance and immersive user experience.

In high-resolution display devices, each pixel includes a light-emitting element and a storage capacitor to store charge and stabilize a driving current supplied to the light emitting element during operation. However, as pixel density increases, the available pixel area becomes severely limited. This reduction in area restricts the size of the capacitor formed within each pixel. As a result, these display devices often suffer from degraded pixel-driving performance, including luminance non-uniformity, flicker, and reduced stability, particularly in applications such as AR, VR, MR, and XR systems that demand precise and stable image rendering.

### SUMMARY

At least one embodiment of the present disclosure provides an ultra-high resolution display device and an electronic apparatus including the same.

An embodiment of the inventive concept provides a display device including a base layer, a first insulation layer disposed on the base layer, an insulation pattern disposed on the first insulation layer, a second insulation layer disposed on the first insulation layer and the insulation pattern, a transistor disposed on a first layer above the base layer, a capacitor disposed on a second layer above the first layer and a light-emitting element disposed on a third layer above the second layer. The capacitor includes a first electrode disposed between the first insulation layer and the second insulation layer, and covering the insulation pattern, and a second electrode disposed on the second insulation layer.

In an embodiment, the insulation pattern may have a shape of a polygonal frustum or a conic frustum.

In an embodiment, an interior angle between a side surface and a top surface of the first insulation layer may be about 50 degrees to about 85 degrees.

In an embodiment, a thickness of the insulation pattern may be about 0.5 μm to about 2 μm, and a diameter of a bottom surface of the insulation pattern or a length of a side of the bottom surface, may be about 1 μm to about 3 μm.

In an embodiment, the second insulation layer may include silicon oxide, silicon oxynitride, or silicon nitride.

In an embodiment, the insulation pattern may be provided as a plurality of patterns that may overlap the first electrode.

In an embodiment, the first electrode and the second electrode may include a long side and a short side, and a length of a longer side among the long side of the first electrode and the long side of the second electrode may be about 5 μm to about 10 μm.

In an embodiment of the inventive concept, a display device includes a base layer, a first insulation layer disposed on the base layer and defining a cavity, a second insulation layer disposed on the first insulation layer, a transistor disposed on a first layer above the base layer, a capacitor disposed on a second layer above the first layer and a light-emitting element disposed on a third layer above the second layer. The capacitor includes a first electrode located between the first insulation layer and the second insulation layer, and located within the cavity, and a second electrode disposed on the second insulation layer.

In an embodiment, the first insulation layer may include an organic material, the second insulation layer may include an inorganic material, and the first insulation layer may be thicker than the second insulation layer.

In an embodiment, the second insulation layer may be located within the cavity, and the second electrode may be located within the cavity.

In an embodiment, a maximum depth of the cavity may be greater than a thickness of the second insulation layer.

In an embodiment of the inventive concept, an electronic apparatus (e.g., an electronic device) includes a display device and a processor configured to control the display device. The display device includes a base layer which has a first pixel region and a second pixel region, a first insulation layer disposed on the base layer, an insulation pattern disposed on the first insulation layer and located in each of the first pixel region and the second pixel region, a second insulation layer disposed on the first insulation layer and the insulation pattern, a transistor disposed on a first layer above the base layer, and located in each of the first pixel region and the second pixel region, a capacitor disposed on a second layer above the first layer, and located in each of the first pixel region and the second pixel region and a light-emitting element on a third layer above the second layer, and located in each of the first pixel region and the second pixel region. The capacitor includes a first electrode which is disposed between the first insulation layer and the second insulation layer to cover the insulation pattern, and a second electrode disposed on the second insulation layer.

In an embodiment, the insulation pattern of the first pixel region and the insulation pattern of the second pixel region may form an integrated shape.

In an embodiment, the insulation pattern may include a first portion extending in a first direction and a second portion extending from the first portion in a second direction crossing the first direction.

In an embodiment, the first electrode may occupy about 50% to about 80% of an area of a corresponding pixel region, in a plan view, among the first pixel region and the second pixel region.

In an embodiment, the insulation pattern may have a shape of a polygonal frustum or a conic frustum, an interior angle between a side surface and a top surface of the first insulation layer may be about 50 degrees to about 85 degrees.

In an embodiment, a thickness of the insulation pattern may be about 0.5 μm to about 2 μm, and a diameter of a bottom surface of the insulation pattern or a length of a side of the bottom surface, may be about 1 μm to about 3 μm.

In an embodiment, the second insulation layer may include silicon oxide, silicon oxynitride, or silicon nitride.

In an embodiment, the insulation pattern may be provided as a plurality of patterns that may overlap the first electrode.

In an embodiment, the first electrode and the second electrode may include a long side and a short side. A length of a longer side among the long side of the first electrode and the long side of the second electrode may be about 5 μm to about 10 μm.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a block diagram of an electronic apparatus according to an embodiment of the inventive concept;

FIG. 2 shows schematic diagrams of electronic apparatuses according to embodiments of the inventive concept;

FIG. 3 is an exploded perspective view of a virtual reality device according to an embodiment of the inventive concept;

FIG. 4 is a perspective view of a display panel according to an embodiment of the inventive concept;

FIGS. 5A to 5C are equivalent circuits of a pixel according to an embodiment of the inventive concept;

FIG. 6 is a cross-sectional view of a display panel according to an embodiment of the inventive concept;

FIG. 7 is a plan view of a first capacitor according to an embodiment of the inventive concept;

FIG. 8 is a cross-sectional view of a first capacitor according to an embodiment of the inventive concept;

FIGS. 9 and 10 comparatively illustrate an effective area of a first electrode;

FIG. 11 is a graph illustrating a relationship between an effective area of a first electrode and a size of an interior angle of an insulation pattern;

FIGS. 12A to 12E are cross-sectional views illustrating a method for manufacturing a first capacitor according to an embodiment of the inventive concept;

FIGS. 13A and 13B are cross-sectional views of an insulation pattern according to an embodiment of the inventive concept;

FIG. 14A is a plan view of pixel regions according to an embodiment of the inventive concept;

FIG. 14B is a cross-sectional view of pixel regions according to an embodiment of the inventive concept;

FIG. 15A is a plan view of pixel regions according to an embodiment of the inventive concept;

FIG. 15B is a first cross-sectional view of pixel regions according to an embodiment of the inventive concept;

FIG. 15C is a second cross-sectional view of pixel regions according to an embodiment of the inventive concept;

FIG. 16 is a plan view of a first capacitor according to an embodiment of the inventive concept; and

FIG. 17 is a cross-sectional view of a first capacitor according to an embodiment of the inventive concept.

### DETAILED DESCRIPTION

It is to be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. Also, in the drawings, dimensions such as the thickness, ratio, and size of the elements represent example embodiments, but these dimensions may be varied in alternate embodiments. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element, component, region, layer or section from another element, component, region, layer, or section. For instance, a first element, component, region, layer, or section discussed below could be termed a second element, component, region, layer, or section without departing from the scope of the inventive concept. Similarly, a second element, component, region, layer, or section could be termed a first element, component, region, layer, or section. In this specification, the singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms have relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components, or combinations thereof, but do not preclude the possibility of the presence or addition of one or more other features, numbers, steps, operations, elements, components, and/or combinations thereof.

Hereinafter, embodiments of the inventive concept are described with reference to the drawings.

Embodiments of the inventive concept relate to a display device and an electronic apparatus that includes the display device. Herein, the term ‘electronic apparatus’ may be used interchangeably with the term ‘electronic device’. display device includes multiple pixels, where each pixel includes a capacitor and a light-emitting element. In a first embodiment, the capacitor includes a first electrode disposed between a first insulation layer and a second insulation layer, where the first electrode covers an insulation pattern (e.g., see IP of FIG. 8) formed on the first insulation layer. In a second embodiment, the capacitor includes a first electrode disposed between the first insulation layer and the second insulation layer, where the first electrode is located within a recessed cavity formed in the first insulation layer. In both embodiments, a second electrode is disposed on the second insulation layer. By shaping the region between the first and second electrodes using the insulation pattern or the recessed cavity, an overlapping surface area between the electrodes is increased, thereby enhancing the capacitance of the capacitor without enlarging the pixel area. As a result, the display device may deliver stable and uniform performance in applications such as AR, VR, MR, and XR.

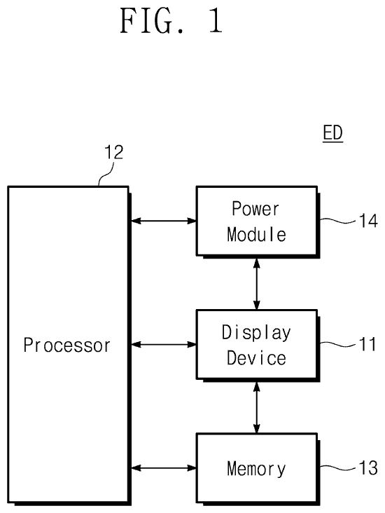

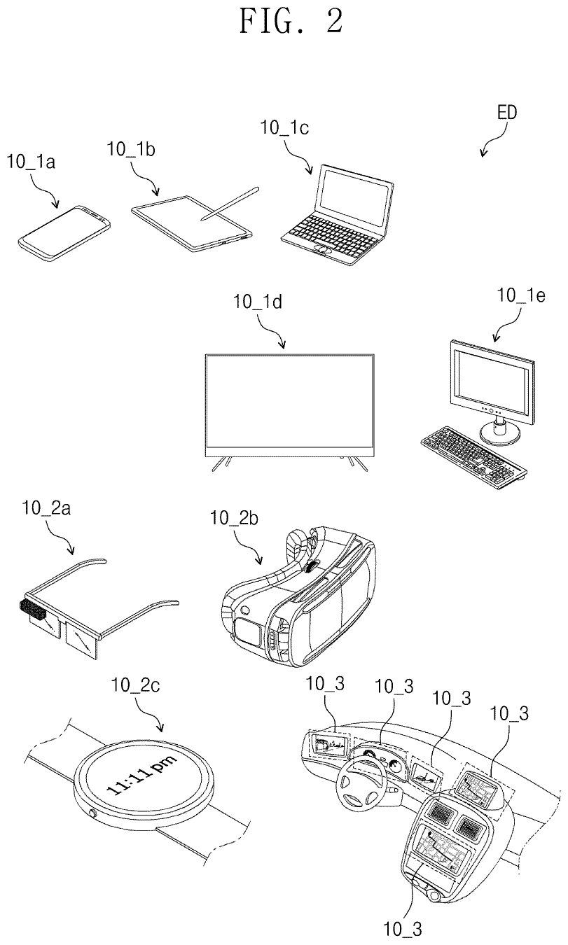

FIG. 1 is a block diagram of an electronic apparatus ED according to an embodiment of the inventive concept. FIG. 2 shows schematic diagrams of electronic apparatuses ED according to embodiments of the inventive concept.

Referring to FIG. 1, the electronic apparatus ED according to an embodiment may include a display device 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

In the memory 13, data information used for an operation of the processor 12 or the display device 11 may be stored. When the processor 12 executes an application stored in the memory 13, an image data signal and/or an input control signal may be transmitted to the display device 11, and the display device 11 may process the received signal and output image information through a display screen of the display device 11.

The power module 14 may include a power supply module such as a power adapter or battery unit, and a power conversion module which converts the power provided by the power supply module and generates power used for an operation of the electronic apparatus ED.

The aforementioned processor 12, power module 14, and memory 13 may be included within the display device 11, or may be disposed separate from the display device 11 as separate modules. The processor 12, the power module 14, and the memory 13 may be located, as a form separated from the display device 11, inside a housing which constitutes an exterior of the electronic apparatus ED.

Referring to FIG. 2, the electronic apparatus ED according to an embodiment of the inventive concept may include not only an electronic apparatus, for information-providing purposes, such as a smart phone 10_1a, a tablet PC 10_1b, a laptop computer 10_1c, a TV 10_1d, and a monitor 10_1e for a desk, but also a wearable electronic apparatus such as smart glasses 10_2a, a head-mounted display device 10_2b, and a smart watch 10_2c, and an electronic apparatus 10_3 for vehicles such as a room mirror display and a center information display (CID), which is disposed on a car's instrument cluster, center fascia, and dashboard. The aforementioned display device 11 may be referred to as a display device DD below.

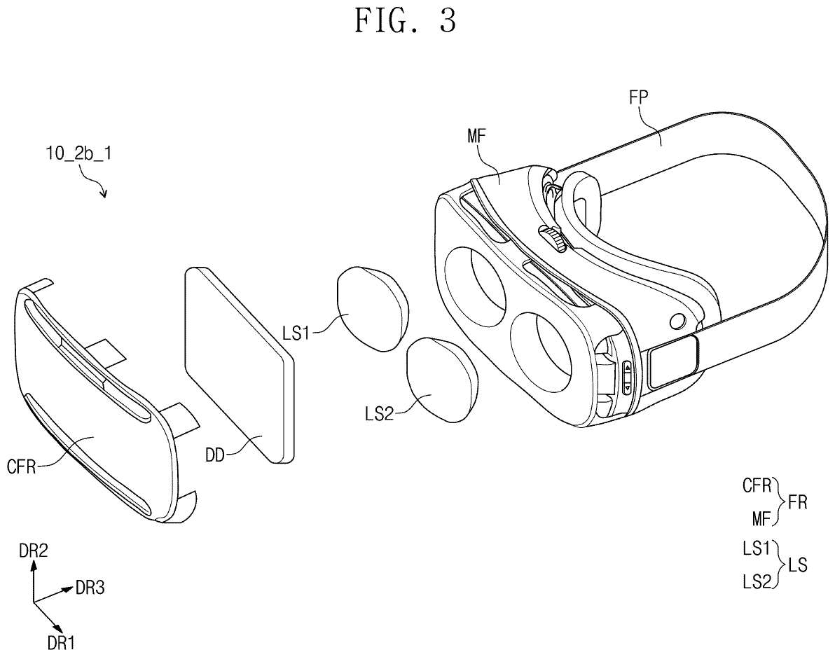

FIG. 3 is an exploded perspective view of a virtual reality device 10_2b_1 according to an embodiment of the inventive concept.

The virtual reality device 10_2b_1 in FIG. 3 may be an example of the head-mounted display device 10_2b illustrated in FIG. 2. The virtual reality device 10_2b_1 in FIG. 3 may be a closed type headset or non-see-through type for providing virtual reality (VR) to a user with a screen that is independent from external objects.

Referring to FIG. 3, the virtual reality device 10_2b_1 may include a display device DD and a lens LS facing the display device DD. In addition, the virtual reality device 10_2b_1 may include a frame FR (or housing) for accommodating the display device DD and the lens LS. The frame FR may include a main frame MF and a cover frame CFR. A fixing part FP may be coupled to the main frame MF and worn on a user's head.

The cover frame CFR may be coupled to the main frame MF, and the lens LS and the display device DD may be disposed in a space between the cover frame and the main frame MF. The main frame MF may provide a space where the lens LS and the display device DD are accommodated.

When the user is wearing the virtual reality device 10_2b_1, the lens LS may be located between the display device DD and the user. The lens LS may transmit an image generated from the display device DD and provide the image to the user. For example, the lens LS may include various types of lenses such as a multi-channel lens, a convex lens, a concave lens, a spherical lens, an aspherical lens, a single lens, a compound lens, a standard lens, a narrow angle lens, a wide angle lens, a fixed focus lens, or a varifocal lens. The lens LS may include a first lens LS1 and a second lens LS2. The first lens LS1 and the second lens LS2 may be arranged to align with the user's left eye and right eye. The display device DD may be coupled to the main frame MF in a fixed configuration, or attached in a detachable configuration.

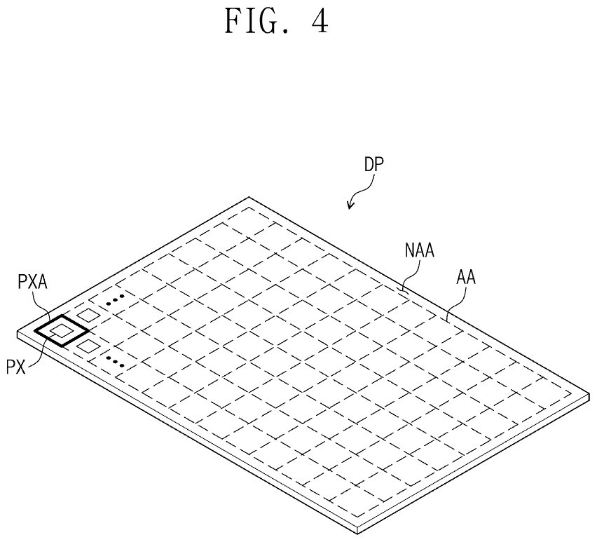

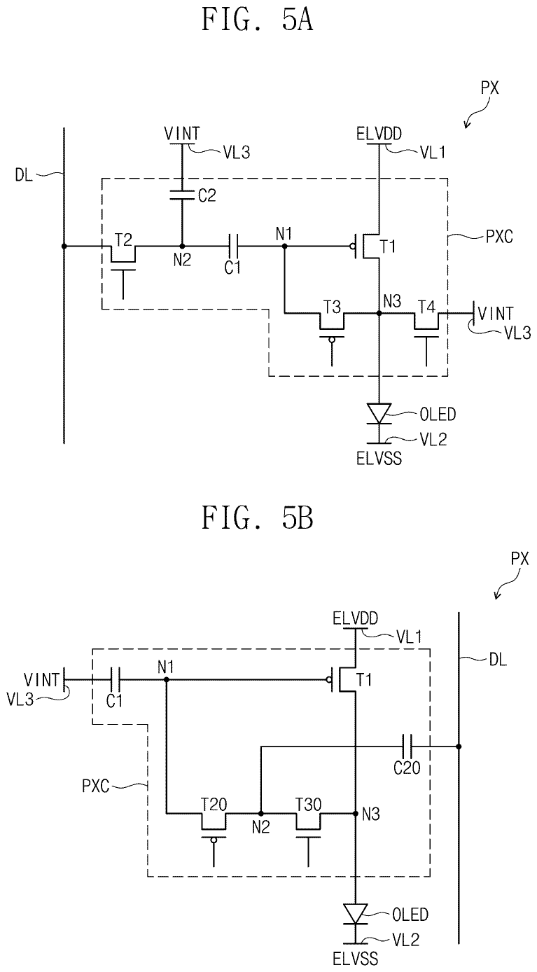

FIG. 4 is a perspective view of a display panel DP according to an embodiment of the inventive concept. FIGS. 5A to 5C are equivalent circuits of a pixel PX according to an embodiment of the inventive concept.

The display device DD described with reference to FIG. 3 includes the display panel DP. Referring to FIG. 4, the display panel DP may include a display region AA and a peripheral region NAA. The peripheral region NAA may surround or be adjacent to the display region AA. The display region AA may include a plurality of pixel regions PXA. The pixels PX may be respectively disposed in the plurality of pixel regions PXA. The pixels PX should not be disposed in the peripheral region NAA.

The pixels PX may each include a light-emitting element and a pixel driving circuit for controlling the light-emitting element. The pixel regions PXA may be substantially divided by the pixel driving circuit. For example, placement of the pixel driving circuit within each pixel may establish the boundaries of the pixel regions PXA in a plan view. The pixel driving circuits of the pixels PX may have the same arrangement or the same layout in each pixel. In an embodiment of the inventive concept, the pixels PX may be divided into two types of the pixels by the layout of the pixel driving circuit. A first type pixel and a second type pixel may be alternately arranged along a row direction.

As resolution increases, the area of the pixel region PXA, in which the pixel driving circuit is disposed, decreases. For example, at a resolution of about 1200 pixels per inch (PPI), the pixel region PXA may have a short side of about 10 μm and a long side of about 20 micrometers (μm). Alternatively, at a resolution of about 1500 PPI, the pixel region PXA may have a short side of about 6 μm and a long side of about 17 μm.

The pixel PX may have any one of equivalent circuits illustrated in FIGS. 5A to 5C. A pixel driving circuit PXC may include a driving transistor T1, a switching transistor T2 or T20, and a first capacitor C1 in common.

Referring to FIG. 5A, the pixel driving circuit PXC may include first to fourth transistors T1 to T4, a first capacitor C1, and a second capacitor C2. In this embodiment, the first and third transistors T1 and T3 are implemented as P-type transistors, and the second and fourth transistors T2 and T4 are implemented as an N-type transistors, but embodiments are not limited thereto.

In this embodiment, the first transistor T1 may be referred to as a driving transistor, and the second transistor T2 may be referred to as a switching transistor. The first transistor T1 is electrically connected between a first voltage line VL1 which receives a first power voltage ELVDD and a light-emitting element OLED. The light-emitting element OLED is electrically connected between a third node N3 and a second voltage line VL2 which receives a second power voltage ELVSS. The first power voltage ELVDD may provide power the light-emitting element OLED. The first power voltage ELVDD may be higher than the second power voltage ELVSS. The first power voltage ELVDD may be a positive voltage and the second power voltage ELVSS may be a ground voltage or a negative voltage.

The second transistor T2 is electrically connected between a data line and a second node N2, and outputs a data signal. The first capacitor C1 is electrically connected between a source of the second transistor T2 and a gate of the first transistor T1, that is, between the second node N2 and a first node N1. The second capacitor C2 is electrically connected between the second node N2 and a third voltage line VL3 which receives a reference voltage VINT.

The third transistor T3 is electrically connected between the gate and a drain, of the first transistor T1, that is, between the first node N1 and the third node N3. The fourth transistor T4 is electrically connected between the third node N3 and the third voltage line VL3 which receives the reference voltage VINT. The fourth transistor T4 may initialize the light-emitting element OLED to the reference voltage VINT. The first capacitor C1 may be initialized to the reference voltage VINT during a period when the third transistor T3 and the fourth transistor T4 are simultaneously or substantially simultaneously turned on.

Referring to FIG. 5B, a pixel driving circuit PXC may include first, second, and third transistors T1, T20, and T30, a first capacitor C1, and a second capacitor C20. In this embodiment, the first and second transistors T1 and T20 are implemented as P-type transistors, and the third transistor T30 is implemented as an N-type transistor, but embodiment are not limited thereto.

The first transistor T1 is electrically connected between a first voltage line VL1 which receives a first power voltage ELVDD and a light-emitting element OLED. The light-emitting element OLED is electrically connected to a second voltage line VL2 which receives a second power voltage ELVSS.

The second transistor T20 is electrically connected between a first node N1, which is a gate of the first transistor T1, and a second node N2. The third transistor T30 is electrically connected between the second node N2 and a third node N3.

The first capacitor C1 is electrically connected between a third voltage line VL3 which receives a reference voltage VINT and the first node N1. The second capacitor C20 is electrically connected between the second node N2 and a data line DL. An electrode of the second capacitor C20 connected to the data line DL may be configured as a portion of the data line DL.

The third transistor T30 of the pixel driving circuit PXC in FIG. 5B may be omitted in a pixel driving circuit PXC in FIG. 5C. Here, a second transistor T20 is directly connected to a third node N3.

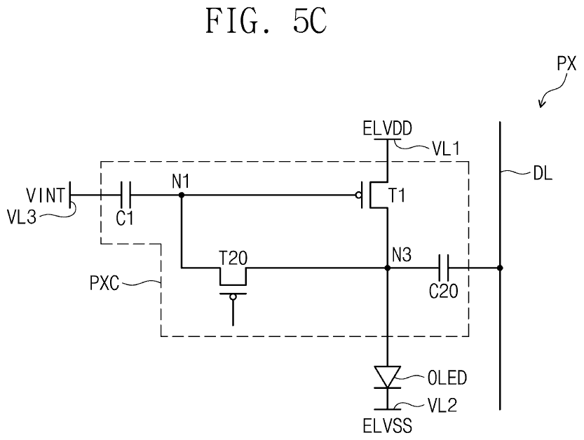

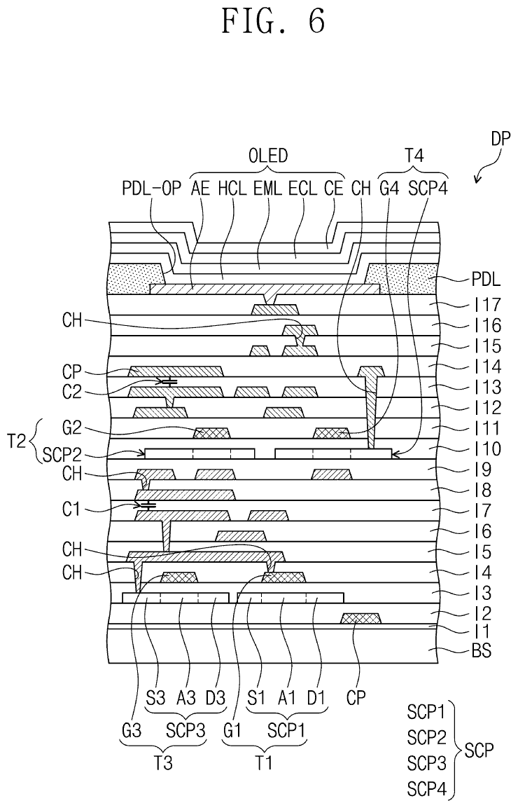

FIG. 6 is a cross-sectional view of a display panel DP according to an embodiment of the inventive concept. FIG. 6 is illustrated based on the pixel PX in FIG. 5A.

The display panel DP includes a plurality of insulation layers I1 to I17 disposed on a base layer BS and a plurality of patterns SCP and CP. FIG. 6 exemplarily illustrates seventeen insulation layers I1 to I17. The seventeen insulation layers I1 to I17 may each include an inorganic material or an organic material. The plurality of patterns SCP and CP may include semiconductor patterns SCP and conductive patterns CP. The semiconductor patterns SCP may include a transistor, and the conductive patterns CP may include a signal line or a circuit element.

The seventeen insulation layers I1 to I17 electrically insulate the semiconductor patterns SCP from the conductive patterns CP in a thickness direction of the display panel DP, and positionally divide (that is, physically separate) the semiconductor patterns and the conductive patterns.

A semiconductor pattern SCP1 of a first transistor T1 and a semiconductor pattern SCP3 of a third transistor T3 may be disposed on the second insulation layer I2. The semiconductor patterns SCP1 and SCP3 may each include a first metal oxide semiconductor. The semiconductor patterns SCP1 and SCP3 may respectively include source regions S1 and S3, channel regions A1 and A3 (or active regions), and drain regions D1 and D3. In an embodiment, the source regions S1 and S3 and the drain regions D1 and D3 are doped regions and respectively have greater conductivity than the channel regions A1 and A3. A gate G1 (or gate electrode) of the first transistor T1 is disposed on the semiconductor pattern SCP1 of the first transistor T1. A gate G3 of the third transistor T3 is disposed on the semiconductor pattern SCP3 of the third transistor T3.

One of the conductive patterns CP may electrically connect the gate G1 of the first transistor T1 and the source region S3 of the third transistor T3. However, the inventive concept is not limited thereto. For example, one conductive pattern CP may also connect the gate G1 of the first transistor T1 and the drain region D3 of the third transistor T3.

A semiconductor pattern SCP2 of a second transistor T2 and a semiconductor pattern SCP4 of a fourth transistor T4 may be disposed on the ninth insulation layer I9. The semiconductor patterns SCP2 and SCP4 may each include a second metal oxide semiconductor. In an embodiment, a gate G2 of the second transistor T2 is disposed on the semiconductor pattern SCP2 of the second transistor T2, and a gate G4 of the fourth transistor T4 is disposed on the semiconductor pattern SCP4 of the fourth transistor T4.

While each of the semiconductor patterns SCP1 and SCP3 includes the first metal oxide semiconductor, and each of the semiconductor patterns SCP2 and SCP4 includes the second metal oxide semiconductor in an embodiment, the inventive concept is not limited thereto. In an embodiment of the inventive concept, the semiconductor patterns SCP1 and SCP3 may each include a low temperature poly silicon, and the semiconductor patterns SCP2 and SCP4 may each include a metal oxide semiconductor.

A pixel-defining film PDL and a light-emitting element OLED are disposed on the seventeenth insulation layer I17. The light-emitting element OLED may include a first electrode AE, a hole control layer HCL, a light-emitting layer EL, an electron control layer ECL, and a second electrode CE. In this embodiment, the first electrode AE may be an anode, and the second electrode CE may be a cathode. The hole control layer HCL may include at least one of a hole injection layer or a hole transport layer, and the electron control layer ECL may include at least one of an electron injection layer or an electron transport layer.

Referring to FIG. 6, the plurality of patterns SCP and CP which are disposed on different layers may be connected through a contact hole CH. The conductive patterns CP disposed on different layers may be connected, or the conductive patterns CP and the semiconductor patterns SCP1, SCP2, SCP3, and SCP4, which are disposed on different layers, may be connected. For example, the conductive patterns CP may be electrically interconnected, and may also be electrically connected to the semiconductor patterns SCP1-SCP4 formed on other layers through respective contact holes.

In an embodiment, two conductive patterns CP, among the plurality of conductive patterns CP, disposed on different layers define a capacitor. Referring to FIG. 6, the conductive pattern CP disposed on the sixth insulation layer I6 and the conductive pattern CP disposed on the seventh insulation layer I7 may define the first capacitor C1 (see FIG. 5A). The conductive pattern CP disposed on the twelfth insulation layer I12 and the conductive pattern CP disposed on the thirteenth insulation layer I13 may define the second capacitor C2 (see FIG. 5A).

In an embodiment, the conductive patterns CP of the first capacitor C1 and the second capacitor C2 are disposed on a different layer from the first to fourth transistors T1 to T4 described above. In other words, the conductive patterns are disposed on a different layer from the semiconductor patterns SCP1 to SCP4 and the gates G1 to G4.

As resolution increases, the area of the pixel region PXA (see FIG. 4) decreases on a plane, and circuit elements have no choice but to be stacked in the thickness direction of the display panel DP. For example, as display resolution increases, a plan view area of the pixel region PXA decreases, which may necessitate the stacking of circuit elements along the thickness direction of the display panel DP. To prevent interference that could occur if multiple circuit elements were formed on a single insulation layer, the circuit elements may be disposed on different layers. As a result, the number of stacked layers of the display panel DP may increase.

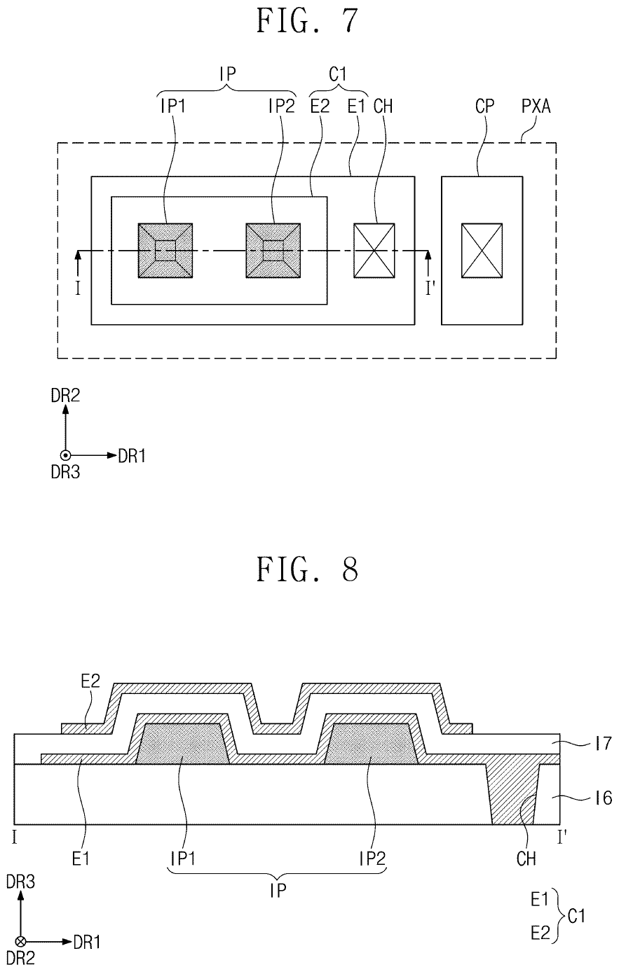

FIG. 7 is a plan view of a first capacitor C1 according to an embodiment of the inventive concept. FIG. 8 is a cross-sectional view of a first capacitor C1 according to an embodiment of the inventive concept.

The first capacitor C1 to be described with reference to FIGS. 7 and 8 includes two conductive patterns CP located between the sixth insulation layer I6 and the eighth insulation layer I8 in FIG. 6. However, embodiment are not limited thereto. For example, the first capacitor C1 may also include conductive patterns CP disposed on different layers. The description of the first capacitor C1 below may be equally applied to the second capacitors C2 and C20 described with reference to FIGS. 5A to 5C.

Two conductive patterns, among the conductive patterns CP described with reference to FIG. 6, which form the first capacitor C1 are respectively referred to as a first electrode E1 and a second electrode E2. In addition, the wording of “the sixth insulation layer I6 to the eighth insulation layer I8” is merely used to distinguish between the seventeen insulation layers I1 to I17 illustrated in FIG. 6, and at least three insulation layers may be included in the first capacitor C1. Accordingly, the term “first to third insulation layers” may be used so as to distinguish the three insulation layers from each other. The three insulation layers may also be referred to as a lower insulation layer, an intermediate insulation layer, and an upper insulation layer, respectively.

Referring to FIGS. 7 and 8, the first capacitor C1 disposed in one pixel region PXA is illustrated, together with one conductive pattern CP spaced apart from the first capacitor C1 are illustrated.

The first electrode E1 and the second electrode E2 overlap each other. The second electrode E2 may be disposed on the first electrode E1. The first electrode E1 and the second electrode E2 may each include a long side and a short side. A length of the long side of the first electrode E1, which is larger among the first electrode E1 and the second electrode E2, may be about 5 μm to about 10 μm. For example, the longer of the long sides of the first electrode E1 and the second electrode E2 may have a length of about 5-10 μm but is not limited thereto. It is exemplarily illustrated that the second electrode E2 is disposed inside the first electrode E1 and has a smaller area than the first electrode E1, on a plane, but embodiments are not limited thereto. For example, while the second electrode E2 is illustrated as being disposed within the first electrode E1 and having a smaller plan view area, embodiments are not limited thereto.

The first electrode E1 may occupy about 20% to about 80%, about 50% to about 80%, or about 70% to about 80% of an area of the pixel region PXA. An occupancy rate of the first electrode E1 with respect to the pixel region PXA may indicate an occupancy rate of the first capacitor C1. For example, if the pixel region PXA is 100 μm² and the first electrode E1 covers 60 μm² in a plan view, the occupancy of the first capacitor C1 would also be 60 μm². An entire area of an insulation pattern IP may occupy about 50% to about 60% of the area of the pixel region PXA.

The first electrode E1 may be connected to patterns SCP and CP disposed thereunder, through a contact hole CH that penetrates the sixth insulation layer I6. For example, the first electrode E1 may be electrically connected to underlying semiconductor patterns SCP and conductive patterns CP through a contact hole CH that penetrates the sixth insulation layer. As illustrated in FIG. 5A, the first electrode E1 may be electrically connected to the first transistor T1 or the second transistor T2.

The insulation pattern IP is disposed on the sixth insulation layer I6. The insulation pattern IP overlaps each of the first electrode E1 and the second electrode E2. First and second insulation patterns IP1 and IP2, which are spaced apart from each other in a first direction DR1, are exemplarily illustrated as the insulation pattern IP.

In an embodiment, the insulation pattern IP has a shape of a polygonal frustum or a conic frustum, but is not limited thereto. The polygonal frustum may refer to a truncated-pyramid geometry having a polygonal base (e.g., square, rectangular, hexagonal) and a smaller, substantially parallel top surface, with sloped sidewalls. The conic frustum may refer to a truncated-cone geometry having a circular (or elliptical) base and a smaller, substantially parallel top surface, with a continuous conical sidewall. In a plan view, the polygonal frustum may appear as a polygon and the conic frustum as a circle. In other embodiments, the insulation pattern IP may have a shape of a polygonal prism, a polyhedron, a cylinder, or a polygonal pyramid. The insulation pattern IP may have a trapezoidal shape on a cross section, but is not limited thereto. The insulation pattern IP may have a shape of a semicircle, polygon, or inverse trapezoid on a cross section.

The insulation pattern IP may include an organic material or an inorganic material. The insulation pattern IP may include silicon oxide (SiOₓ), silicon nitride (SiNₓ), silicon oxynitride (SiOₓN_{y}), photoresist, or photosensitive polymer, for example, photosensitive polyimide. The insulation pattern IP may correspond to a hill which has an effect on the shape and an effective area of the first electrode E1 and the second electrode E2. The insulation pattern IP may be a raised three-dimensional bump, and the first electrode E1 and the second electrode E2 of the capacitor may conform to the bump. For example, by draping over the top and sidewalls of the insulation pattern IP, the electrodes E1 and E2 may gain additional opposing (effective) area, thereby increasing a capacitance of the capacitor.

A thickness of the insulation pattern IP may be about 0.5 μm to about 2 μm. A length of a bottom surface of the insulation pattern IP may be about 1 μm to about 3 μm. When the insulation pattern IP has a shape of a cylinder or conic frustum, the length of the bottom surface may correspond to a diameter of the bottom surface.

The first electrode E1 may cover the insulation pattern IP. That is, the first electrode E1 may be in contact with a remaining region (or remaining external surface) other than a region (or one external surface) that is in contact with a top surface of the sixth insulation layer I6 of the insulation pattern IP. For example, when the insulation pattern IP has a shape of a quadrangular frustum, the first electrode E1 may be in contact with a side surface and top surface of the insulation pattern IP. The first electrode E1 may also be in contact with the top surface of the sixth insulation layer I6. In an embodiment, the first electrode E1 disposed on the sixth insulation layer I6 has a curved shape. For example, when the first electrode E1 conforms to the insulation pattern IP, the first electrode may exhibit a non-planar (curved) profile over the sixth insulation layer I6.

The first electrode E1 may have a single-layer structure, or a multi-layer structure laminated along a thickness direction. For example, the first electrode E1 may have a single-layer structure, or a multi-layer structure formed along the thickness direction. The first electrode E1 of the multi-layer structure may include at least two metal layers. A conductive pattern of the multi-layer structure may include metal layers having different metals. In an embodiment having the multi-layer structure including the metal layers having different metals, the first electrode E1 may include a titanium layer, an aluminum layer, and a titanium layer which are continuously laminated. For example, the titanium layer, the aluminum layer, and the titanium layer that form the first electrode E1 may be deposited sequentially in the thickness direction. The second electrode E2 to be described later may also have a single-layer or multi-layer structure. The second electrode E2 may also include a titanium layer, an aluminum layer, and a titanium layer which are laminated. For example, the titanium layer, the aluminum layer, and the titanium layer that form the second electrode E2 may be deposited sequentially in the thickness direction

A seventh insulation layer I7 is disposed on the first electrode E1. The seventh insulation layer I7 may include an inorganic material. The seventh insulation layer I7 with the inorganic material may be formed to have a small thickness, thereby reducing a distance between the first electrode E1 and the second electrode E2. In an embodiment, a thickness of the seventh insulation layer I7 is inversely proportional to a capacitance of the first capacitor C1. The seventh insulation layer I7 may include silicon oxide (SiOₓ), silicon nitride (SiNₓ), silicon oxynitride (SiOₓN_{y}), aluminum oxide (AlOₓ), or titanium oxide (TiOₓ).

The seventh insulation layer I7 when an inorganic layer may be formed through deposition to have a uniform thickness. The seventh insulation layer I7 formed through the deposition may have a shape of a lower side transferred to the seventh insulation layer I7. For example, the seventh insulation layer (I7) may replicate the underlying topography, such as the contours of the first electrode and the insulation pattern IP rather than forming a flat film. The seventh insulation layer I7 may have a shape, that is, a curved shape, similar to the shape of the first electrode E1 disposed under the seventh insulation layer I7.

The second electrode E2 is disposed on the seventh insulation layer I7. Thus, when the seventh insulation layer I7 is curved, the second electrode E2 disposed on the seventh insulation layer I7 may also have a curved shape. As a result, each of the first electrode E1, the seventh insulation layer I7, and the second electrode E2 may have the curved shape due to the insulation pattern IP. When the first electrode E1, the seventh insulation layer I7, and the second electrode E2 have the curved shape, an interfacing area (hereinafter, effective area) between the first electrode E1 and the second electrode E2 may increase. The effective area may have a direct effect on the capacitance of the first capacitor C1. For example, the capacitance of the first capacitor C1 may increase as the effective area between the electrodes E1 and E2 increases.

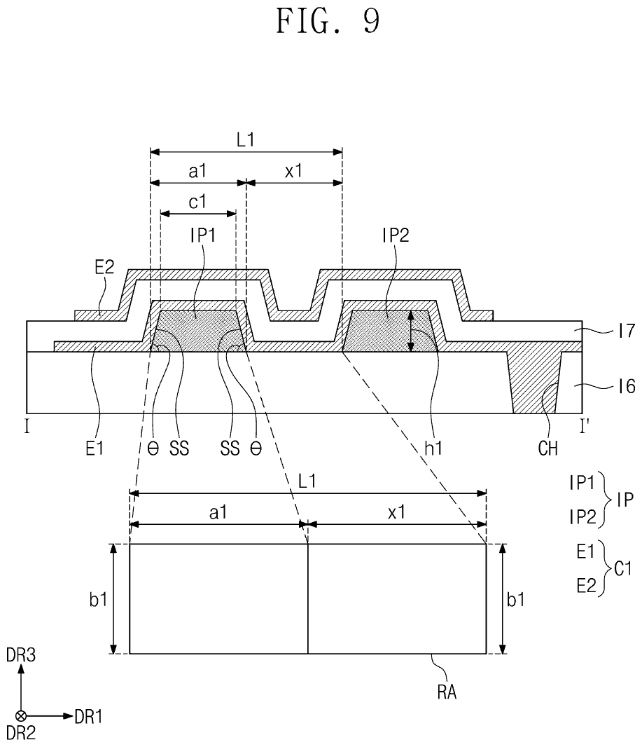

FIGS. 9 and 10 comparatively illustrate an effective area of a first electrode which varies depending on presence of an insulation pattern IP. FIG. 11 is a graph illustrating a relationship between an effective area of a first electrode and an interior angle of an insulation pattern.

In FIGS. 9 and 10, a region corresponding to one insulation pattern IP and a region between the adjacent insulation patterns IP are configured as a reference region RA. At least one reference region RA may be configured in a first electrode E1, and the first electrode E1 may have a greater area than the reference region configured therein.

FIG. 9 illustrates a length L1 of the reference region RA in a first direction DR1. The length L1 of the reference region RA in the first direction DR1 may be represented using the insulation pattern IP. The length L1 of the reference region RA in the first direction DR1 may be equal to a sum of a length al of a bottom surface of one insulation pattern IP in the first direction DR1 and a length xl of the region between the adjacent insulation patterns IP in the first direction DR1. A length of the reference region RA in a second direction DR2 may be equal to a length b1 of a bottom surface of one insulation pattern IP in the second direction DR2.

In the absence of the insulation pattern IP, the effective area of the first electrode E1 within the reference region RA is substantially equal to an area of the reference region RA on a plane. FIG. 9 illustrates the reference region RA in a plan view.

Referring to FIG. 10, an effective length L2 of the first electrode E1 increases compared to the length L1 of the reference region RA in FIG. 9. When the first electrode E1 surrounds the insulation pattern IP, the area of the first electrode E1 may increase as much as an area of a side surface of the insulation pattern IP. However, since an area of a top surface of the insulation pattern IP may decrease by an amount according to an interior angle θ, compared to an area of a bottom surface of the insulation pattern IP, this decreased amount may be taken into account when measuring an amount of increase in area between the area of the first electrode E1 in FIG. 9 and the area of the first electrode E1 in FIG. 10.

As described with reference to FIG. 8, the second electrode E2 has a shape similar to that of the first electrode E1 since the curve of the first electrode E1, which is under the second electrode E2, is transferred to the second electrode E2. For example, the second electrode E2 may assume a profile similar to the first electrode E1 because the curvature of E1 is replicated in the seventh insulation layer I7, and the second electrode E2 formed on seventh insulation layer I7 follows that curvature. Accordingly, the second electrode E2 also has a region corresponding to the side surface of the insulation pattern IP. A facing area between the first electrode E1 and the second electrode E2 may increase by virtue of the region corresponding to the side surface of the insulation pattern IP, and thus capacitance of a first capacitor C1 may increase.

The capacitance of the first capacitor C1 may increase proportionally to the size and number of the insulation pattern IP overlapping the first capacitor C1. The capacitance of the first capacitor C1 may increase proportionally to the height and taper angle (or the above interior angle θ) of the insulation pattern IP.

In FIG. 11, a first graph GH1 is related to Equation 1 below, and a second graph GH2 is related to Equation 2 below.

The length L1 of the reference region RA described with reference to FIGS. 9 and 10 may be expressed as in Equation 1, using the insulation pattern IP. When the insulation pattern IP is not disposed, the length L1 of the reference region RA is equal to the effective length L2 of the first electrode E1 within the reference region RA.

Referring to FIGS. 9 and 10, one insulation pattern IP may have two side surfaces SS facing each other in the first direction DR1. In this embodiment, the two side surfaces SS may each define the interior angle θ with a top surface of a sixth insulation layer I6. In Equation 1, cl is a length of the top surface of the insulation pattern IP within the first direction DR1. Further, in Equation 1, hl is a thickness of the insulation pattern IP within a third direction DR3.

$$L 1 = c 1 + x 1 + 2 \times \frac{h 1}{tan θ} \qquad [ Equation 1 ]$$

Referring to FIG. 10, when one insulation pattern IP is disposed, the effective length L2 of the first electrode E1 within the reference region RA may be expressed as in Equation 2, using the insulation pattern IP.

$$L 2 = c 1 + x 1 + 2 \times \frac{h 1}{sin θ} \qquad [ Equation 2 ]$$

Referring to Equation 1 and Equation 2, the effective length L2 of the first electrode E1 within the reference region RA varies depending on the presence or absence of the insulation pattern IP within the reference region RA. When the effective length L2 of the first electrode E1 increases, the effective area of the first electrode E1 also increases. For example, the effective length L2 increases when the insulation pattern IP is present.

According to Equation 1 and Equation 2, a size of the interior angle θ may be one element in determining the effective length L2 of the first electrode E1. When the interior angle θ is about 50 degrees or more, the insulation pattern IP has an effective effect on the increase of the effective length L2 of the first electrode E1. When the interior angle θ is about 60 degrees, the last element

$$( e . g . , \frac{h 1}{sin θ} )$$

in Equation 2 may correspond to twice the last element

$$( e . g . , \frac{h 1}{tan θ} )$$

### in Equation 1.

According to FIG. 11, setting the interior angle θ to about 50 degrees or greater may increase the effective length L2 of the first electrode E1. The interior angle θ may be set smaller than a right angle or 90 degrees to enhance reliability in a photolithography and/or etch process used to form the insulation pattern IP. Accordingly,
the interior angle θ may be about 85 degrees or less.

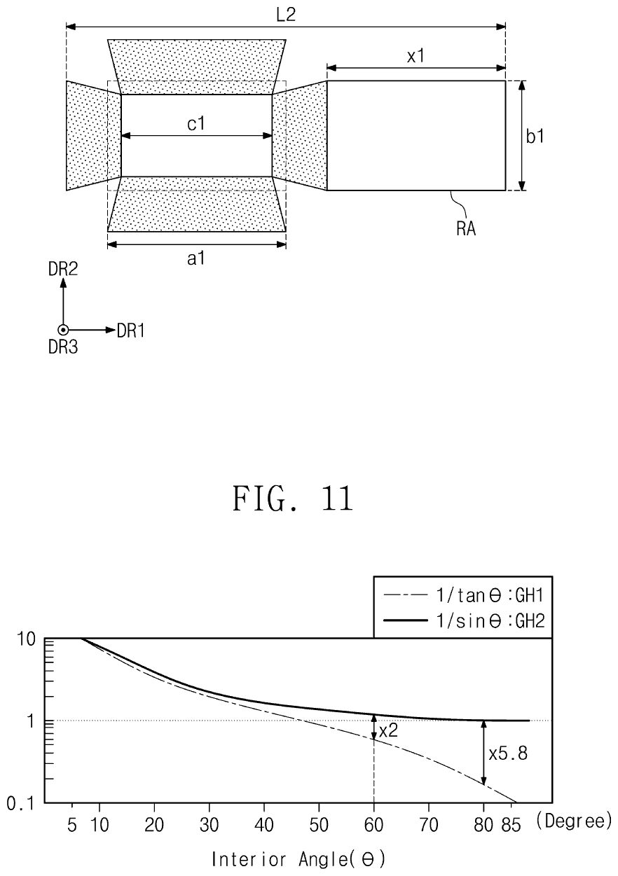

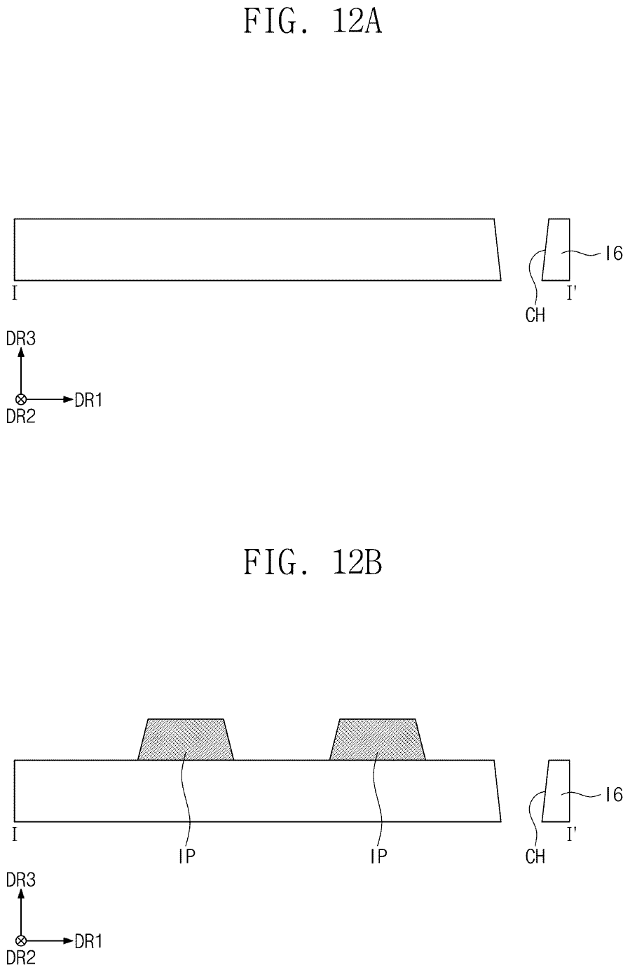

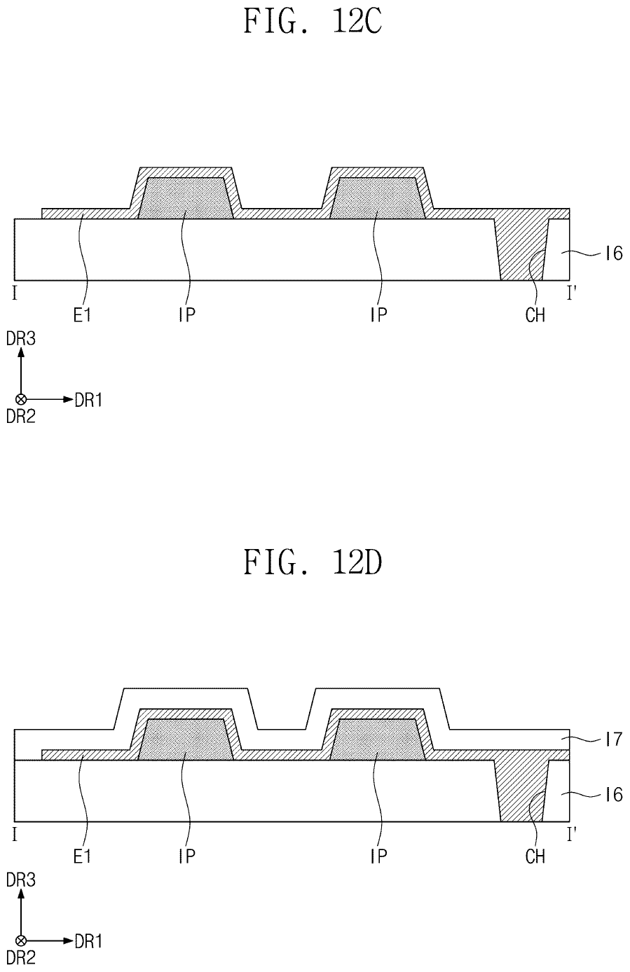

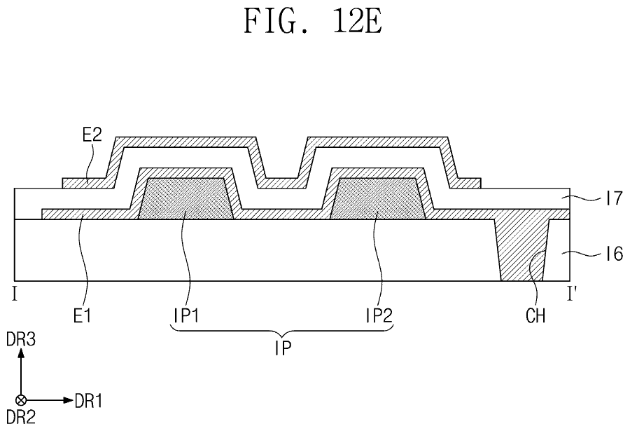

FIGS. 12A to 12E are cross-sectional views illustrating a method for manufacturing a first capacitor C1 according to an embodiment of the inventive concept.

FIGS. 12A to 12E illustrate some processes in a method for manufacturing a display panel, according to an embodiment of the inventive concept. The display panel illustrated in FIG. 6 may be formed through steps that precede and follow the processes illustrated in FIGS. 12A to 12E. The steps that precede and follow the above processes are not particularly limited.

Referring to FIG. 12A, a sixth insulation layer I6 is formed, and a contact hole CH is formed in the sixth insulation layer I6. The sixth insulation layer I6 may be formed through a physical vapor deposition (PVD) method, a chemical vapor deposition (CVD) method, and/or a sol-gel process. For example, the sixth insulation layer I6 including an inorganic material may be formed through the chemical vapor deposition (CVD) method. The sixth insulation layer I6 including an organic material may be formed through a coating process.

A photoresist layer may be formed on the sixth insulation layer I6 with the inorganic material, and the contact hole CH may be formed using exposure, development, and etching processes. In the sixth insulation layer I6 with the organic material, more specifically, the sixth insulation layer I6 including a photosensitive organic material, the contact hole CH may be formed by directly exposing the sixth insulation layer I6, and then developing the sixth insulation layer I6, without the photoresist layer.

Next, referring to FIG. 12B, an insulation pattern IP may be formed on the sixth insulation layer I6. For example, an insulation layer may be deposited on the sixth insulation layer I6 and patterned using exposure and development processes to form the insulation pattern IP.

Then, referring to FIG. 12C, a first electrode E1 is formed. For example, the first electrode E1 may be formed on the insulation pattern IP. For example, a metal layer may be deposited on the insulation pattern IP and patterned using a photolithography process to form the first electrode E1.

Subsequently, as shown in FIG. 12D, a seventh insulation layer I7 may be deposited to cover the first electrode E1. For example, an inorganic material or dielectric may be deposited by a conformal process. The conformal process may be a deposition method that coats surfaces uniformly and follows the underlying topography.

Thereafter, as illustrated in FIG. 12E, a second electrode E2 is formed. For example, the second electrode E2 may be formed on the seventh insulation layer I7. For example, a metal layer may be deposited and patterned through a photolithography process to form the second electrode E2.

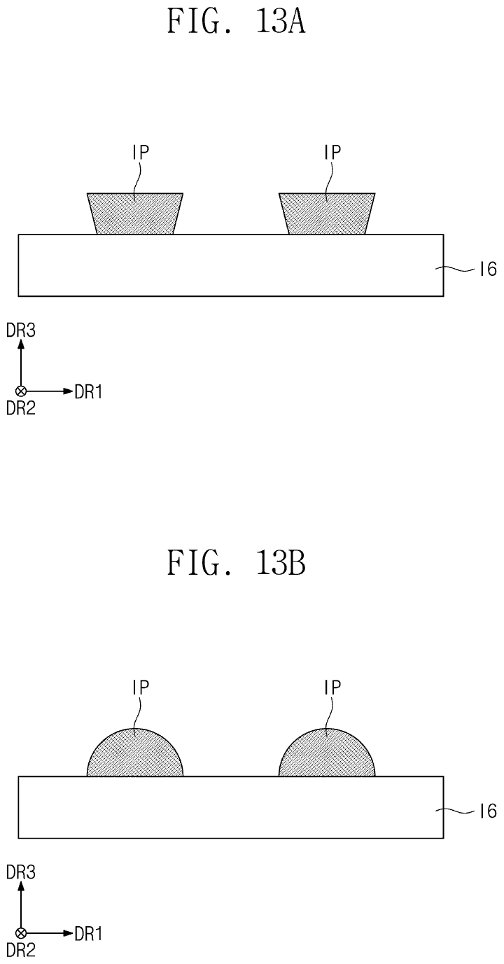

FIGS. 13A and 13B are cross-sectional views of an insulation pattern IP according to an embodiment of the inventive concept.

The insulation pattern IP with a shape of a quadrangular frustum is described as one example with reference to FIGS. 7 to 11. According to an embodiment of the inventive concept, the insulation pattern IP may be deformed into various shapes.

As illustrated in FIG. 13A, the insulation pattern IP may have a shape of an inverted quadrangular frustum. A cross section of the insulation pattern IP has a shape of an inverted trapezoid. The insulation pattern IP may also be described as having an inverted taper shape.

When an insulation layer used to form the insulation pattern IP includes or is a negative type photosensitive material, an unexposed region may be removed during development. Since exposure amount of the insulation layer is inversely proportional to a depth of the insulation layer, a lower side of the insulation layer is less exposed and is more developed, thereby forming the insulation pattern IP illustrated in FIG. 13A.

As illustrated in FIG. 13B, an insulation pattern IP may have a dome shape (or hemisphere shape). A cross section of the insulation pattern IP may have a semicircular shape.

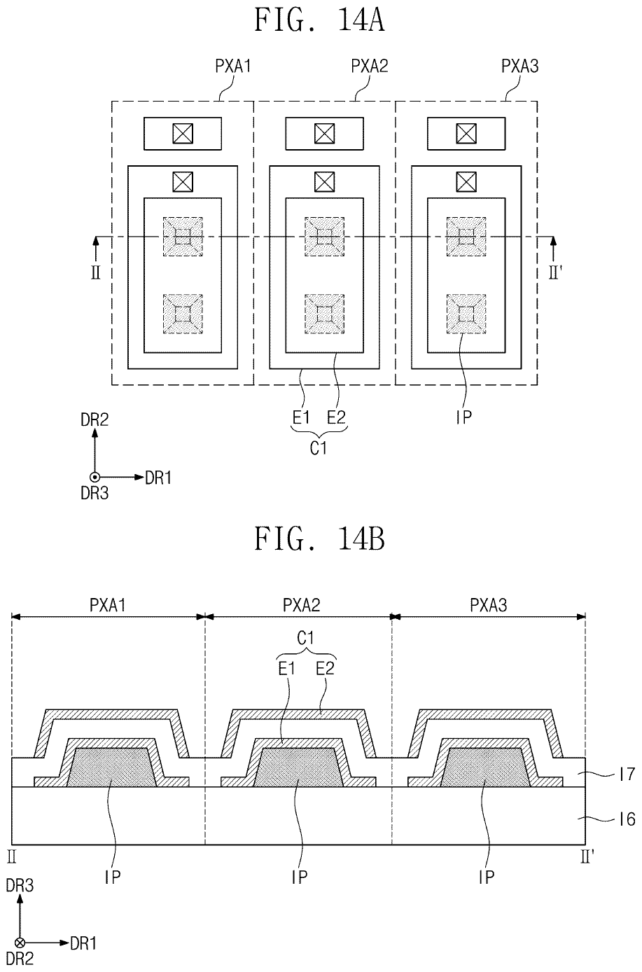

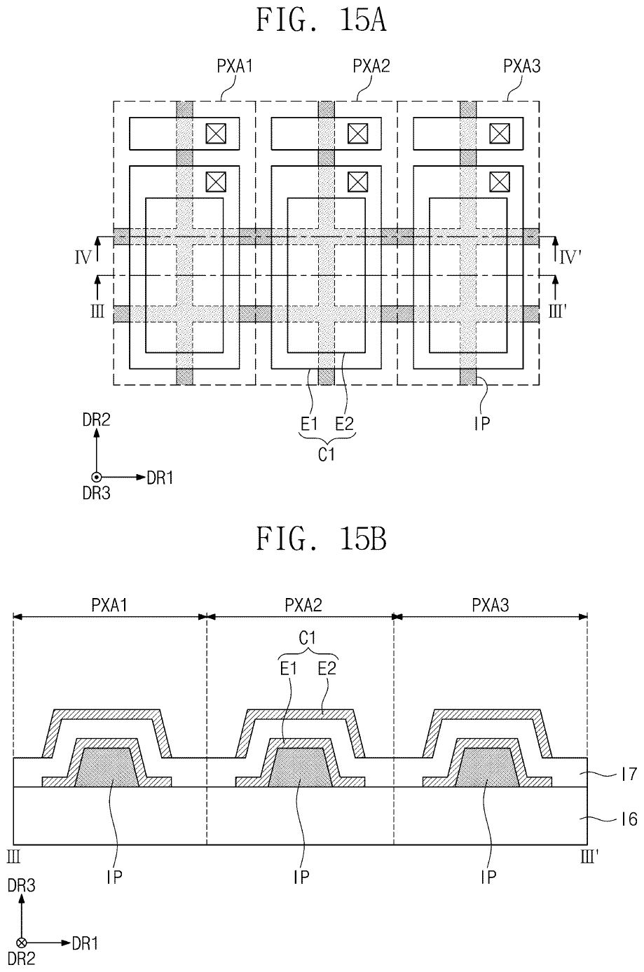

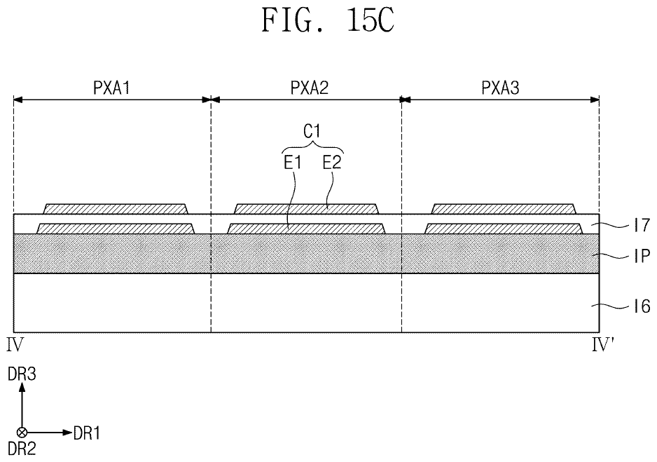

FIG. 14A is a plan view of pixel regions PXA according to an embodiment of the inventive concept. FIG. 14B is a cross-sectional view of pixel regions PXA according to an embodiment of the inventive concept. FIG. 15A is a plan view of pixel regions PXA according to an embodiment of the inventive concept. FIG. 15B is a first cross-sectional view of pixel regions PXA according to an embodiment of the inventive concept. FIG. 15C is a second cross-sectional view of pixel regions PXA according to an embodiment of the inventive concept.

FIGS. 14A and 14B illustrate first to third pixel regions PXA1, PXA2, and PXA3 which are adjacent to each other. The first to third pixel regions PXA1, PXA2, and PXA3 may have the same arrangement of insulation patterns IP and the same arrangement of conductive patterns CP. Accordingly, an occupancy rate of a first capacitor C1 with respect to the pixel region PXA may be equal in the first to the third pixel regions PXA1, PXA2, and PXA3.

A distance between adjacent first electrodes E1 among the first electrodes E1 of the first to third pixel regions PXA1, PXA2, and PXA3 may be greater than about 1 μm. The above distance may be measured within a first direction DR1. For example, the spacing between adjacent first electrodes E1 in the first to third pixel regions PXA1, PXA2, and PXA3 may be greater than about 1 μm, measured along the first direction DR1.

Referring to FIGS. 15A to 15C, an insulation pattern IP of first to third pixel regions PXA1, PXA2, and PXA3 may have an integrated shape or be a continuous structure. In other words, portions of the insulation pattern IP are respectively disposed in the first to third pixel regions PXA1, PXA2, and PXA3. The insulation pattern IP may include a horizontally extending portion (or extending portion in a first direction) and a vertically extending portion (or extending portion in a second direction). The insulation pattern IP illustrated in FIG. 15A may include two horizontally extending portions and vertically extending portions extending from the two horizontally extending portions. In an embodiment, one vertically extending portion may overlap other pixel regions disposed adjacent to each other in a vertical direction. For example, a vertically extending portion of the insulation pattern IP may extend across the boundaries of vertically adjacent pixel regions, overlapping those regions in a plan view.

When the insulation pattern IP includes only one among the horizontally extending portion and the vertically extending portion, an area of a side surface of the insulation pattern IP may increase, compared to the insulation pattern IP with a net shape illustrated in FIGS. 15A and 15B, and thus the capacitance of the first capacitor C1 may be increased. For example, as shown in FIG. 15A, the insulation pattern IP may assume a net-like plan-view shape, i.e., integrally formed horizontally and vertically extending portions that traverse the first through third pixel regions PXA1, PXA2 and PXA3.

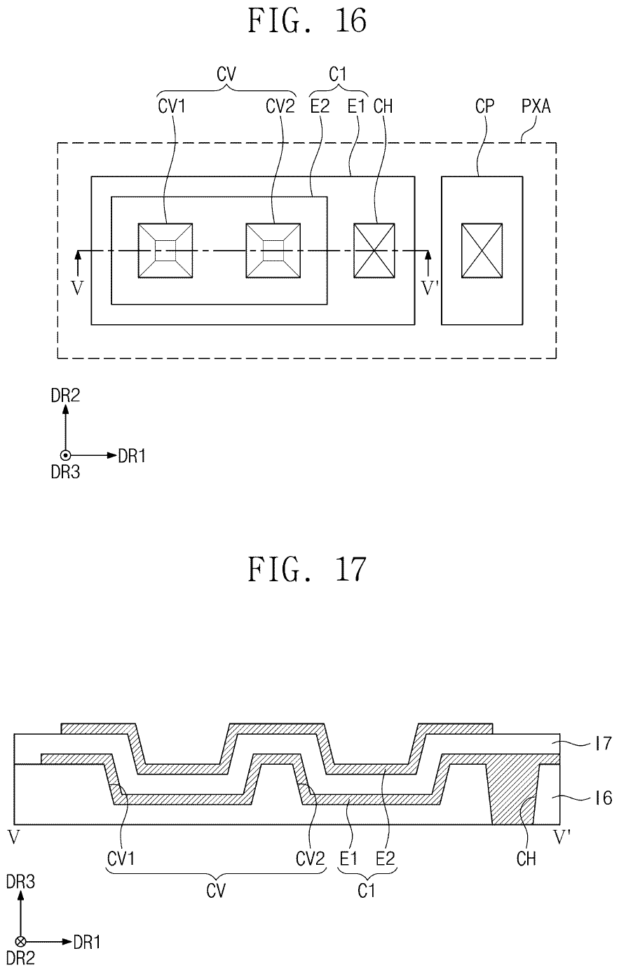

FIG. 16 is a plan view of a first capacitor C1 according to an embodiment of the inventive concept. FIG. 17 is a cross-sectional view of the first capacitor C1 of FIG. 16 according to an embodiment of the inventive concept. Hereinafter, the first capacitor C1 according to this embodiment will be described with reference to FIGS. 16 and 17. However, a description of the same component as the first capacitor C1 described with reference to FIGS. 7 to 15B refers to the description made with reference to FIGS. 7 to 15B. For example, except for the replacement of the insulation pattern IP with a recessed cavity CV (e.g., a valley), the other structural and functional components of the first capacitor C1 shown in FIGS. 16 and 17 may be the same as those described with reference to FIGS. 7 to 15B.

The insulation pattern IP described with reference to FIGS. 7 to 11 may be replaced by the cavity CV (or valley) defined in a sixth insulation layer I6. First and second cavities CV1 and CV2 are exemplarily illustrated. The cavity CV corresponds to a recessed insulation pattern. FIGS. 16 and 17 exemplarily illustrate the cavity CV with a shape that is inverted from the insulation pattern IP described with reference to FIGS. 7 to 15B.

In this embodiment, the cavity CV is illustrated as being formed by removing a portion of the sixth insulation layer I6. However, the cavity CV may penetrate the entire thickness of the sixth insulation layer I6 when no conductive pattern is present beneath the sixth insulation layer I6. Here, a first electrode E1 may be in contact with a top surface of the fifth insulation layer I5 (see FIG. 6).

The sixth insulation layer I6 may have an increased thickness to enlarge a volume of the cavity CV. In addition, the sixth insulation layer I6 may include an organic layer. The sixth insulation layer I6 may include a photosensitive organic material.

The relationship between a surrounding configuration and the insulation pattern IP described with reference to FIGS. 7 to 15B may likewise apply to the relationship between a surrounding configuration and the cavity CV. For example, the cavity CV may be disposed inside the first electrode E1 on a plane. For example, the cavity CV may be positioned within a boundary of the first electrode E1 when viewed in a plan view.

An entire area of the cavity CV may occupy about 50% to about 60% of an area of a pixel region PXA. An area of the first electrode E1 may occupy about 60% to about 80% of the area of the pixel region PXA.

The cavity CV may also have a shape of an inverse trapezoid on a cross section. In the same manner that the first electrode E1 is disposed on a side surface of the insulation pattern IP to increase the area, a substantial area of the electrode overlapping the cavity CV may increase since the first electrode E1 is disposed on both a side surface and a bottom surface of the cavity CV.

A seventh insulation layer I7, which is disposed on the first electrode E1, and a second electrode E2 may also have a curved shape similar to that of the first electrode E1. A portion of the seventh insulation layer I7 and a portion of the second electrode E2 may also be disposed inside the cavity CV. A maximum depth of the cavity CV may be greater than a thickness of the seventh insulation layer I7.

According to embodiments of the inventive concept, an overlapping area between first and second electrodes E1 and E2 of a capacitor may be increased by the geometry of either the insulation pattern IP or the cavity CV, thereby increasing a capacitance of the capacitor.

The foregoing description has been provided with reference to various embodiments of the inventive concept. However, those skilled in the art will appreciate that various modifications and changes may be made without departing from the spirit and scope of the inventive concept.

Therefore, the technical scope of the inventive concept is not to be limited to the contents described herein.

What is claimed is:

1. A display device comprising:
a base layer;
a first insulation layer disposed on the base layer;
an insulation pattern disposed on the first insulation layer;
a second insulation layer disposed on the first insulation layer and the insulation pattern;
a transistor disposed on a first layer above the base layer;
a capacitor disposed on a second layer above the first layer; and
a light-emitting element disposed on a third layer above the second layer,
wherein the capacitor comprises:
a first electrode disposed between the first insulation layer and the second insulation layer, the first electrode covering the insulation pattern; and
a second electrode disposed on the second insulation layer.

2. The display device of claim 1, wherein the insulation pattern has a shape of a polygonal frustum or a conic frustum.

3. The display device of claim 1, wherein an interior angle between a side surface and a top surface of the first insulation layer is about 50 degrees to about 85 degrees.

4. The display device of claim 1, wherein a thickness of the insulation pattern is about 0.5 micrometers (μm) to about 2 μm, and
a diameter of a bottom surface of the insulation pattern or a length of a side of the bottom surface is about 1 μm to about 3 μm.

5. The display device of claim 1, wherein the second insulation layer comprises silicon oxide, silicon oxynitride, or silicon nitride.

6. The display device of claim 1, wherein the insulation pattern is provided as a plurality of patterns that overlap the first electrode.

7. The display device of claim 1, wherein the first electrode and the second electrode comprise a long side and a short side, and
a length of a longer side among the long side of the first electrode and the long side of the second electrode is about 5 μm to about 10 μm.

8. A display device comprising:
a base layer;
a first insulation layer disposed on the base layer and defining a cavity;
a second insulation layer disposed on the first insulation layer;
a transistor disposed on a first layer above the base layer;
a capacitor disposed on a second layer above the first layer; and
a light-emitting element disposed on a third layer above the second layer,
wherein the capacitor comprises:
a first electrode disposed between the first insulation layer and the second insulation layer and located within the cavity; and
a second electrode disposed on the second insulation layer.

9. The display device of claim 8, wherein:
the first insulation layer comprises an organic material;
the second insulation layer comprises an inorganic material; and
the first insulation layer is thicker than the second insulation layer.

10. The display device of claim 9, wherein:
the second insulation layer is located within the cavity; and
the second electrode is located within the cavity.

11. The display device of claim 8, wherein a maximum depth of the cavity is greater than a thickness of the second insulation layer.

12. An electronic device comprising:
a display device; and
a processor configured to control the display device,
wherein the display device comprises:
a base layer comprising a first pixel region and a second pixel region;
a first insulation layer disposed on the base layer;
an insulation pattern disposed on the first insulation layer and located in each of the first pixel region and the second pixel region;
a second insulation layer disposed on the first insulation layer and the insulation pattern;
a transistor disposed on a first layer above the base layer, and located in each of the first pixel region and the second pixel region;
a capacitor disposed on a second layer above the first layer, and located in each of the first pixel region and the second pixel region; and
a light-emitting element disposed on a third layer above the second layer, and located in each of the first pixel region and the second pixel region,
wherein the capacitor comprises a first electrode disposed between the first insulation layer and the second insulation layer to cover the insulation pattern, and a second electrode disposed on the second insulation layer.

13. The electronic device of claim 12, wherein the insulation pattern of the first pixel region and the insulation pattern of the second pixel region form an integrated shape.

14. The electronic device of claim 13, wherein the insulation pattern comprises:
a first portion extending in a first direction; and
a second portion extending from the first portion in a second direction crossing the first direction.

15. The electronic device of claim 12, wherein the first electrode occupies about 50% to about 80% of an area of a corresponding pixel region, in a plan view, among the first pixel region and the second pixel region.

16. The electronic device of claim 12, wherein the electronic device is a virtual reality (VR) device.

17. The electronic device of claim 12, wherein the insulation pattern has a shape of a polygonal frustum or a conic frustum,
an interior angle between a side surface and a top surface of the first insulation layer is about 50 degrees to about 85 degrees.

18. The electronic device of claim 12, wherein a thickness of the insulation pattern is about 0.5 micrometers (μm) to about 2 μm, and a diameter of a bottom surface of the insulation pattern or a length of a side of the bottom surface is about 1 μm to about 3 μm.

19. The electronic device of claim 12, wherein the insulation pattern is provided as a plurality of patterns that overlap the first electrode.

20. The electronic device of claim 12, wherein the first electrode and the second electrode comprise a long side and a short side, and
a length of a longer side among the long side of the first electrode and the long side of the second electrode is about 5 μm to about 10 μm.
